(19) United States
(12) Patent Application Publication
(10) Pub. No.: US 2025/0217250 A1
(43) Pub. Date: Jul. 3, 2025

(54) MEMORY DEVICE AND TESTING METHOD THEREOF

(71) Applicant: SK hynix Inc., Gyeonggi-do (KR)

(72) Inventor: Seung Min BAEK, Gyeonggi-do (KR)

(21) Appl. No.: 18/679,452

(22) Filed: May 31, 2024

(30) Foreign Application Priority Data
Dec. 29, 2023 (KR) 10-2023-0197276

(51) Int. Cl. G06F 11/263

(52) U.S. Cl. CPC G06F 11/263

(57) ABSTRACT

Disclosed is a memory device and a testing method thereof, and the memory device may include a memory circuit generating a plurality of test data in a test mode, a plurality of comparator groups generating first comparison signals based on part of the plurality of test data and part of a plurality of reference data, and generating second comparison signals based on remaining test data and remaining reference data, an error counter generating first symbol information indicating a first number of errors occurring in the part of the plurality of test data, based on the first comparison signals, and generating second symbol information indicating a second number of errors occurring in the remaining test data, based on the second comparison signals, and an error determiner generating a pass/fail signal indicating whether the memory circuit is normal, based on the first and second symbol information.

CROSS-REFERENCE TO RELATED APPLICATION(S)

This application claims priority under 35 U.S.C. § 119 to Korean Patent Application No. 10-2023-0197276, filed on Dec. 29, 2023, the disclosure of which is incorporated herein by reference in its entirety.

### BACKGROUND

### 1. Field

Various embodiments of the present disclosure relate to a semiconductor design technique, and more particularly, to a memory device and a testing method thereof.

### 2. Description of the Related Art

When a defect occurs in a memory cell included in a memory device, various technologies are used to repair the memory cell in which the defect occurs (hereinafter referred to as a “defective cell”). Mainly, a redundancy repair technology in which the defective cell is replaced with a normal memory cell and an error correction code (ECC) technology in which data (i.e., error bits) read from the defective cell is corrected using an ECC function are used. Herein, the ECC technology may include an on-chip ECC technology in which the ECC function is performed in the memory device and an off-chip ECC technology in which the ECC function is performed in a control device that externally controls the memory device.

### SUMMARY

Various embodiments of the present disclosure are directed to a memory device having a test scheme optimized according to a level of error correction capability, and a testing method of the memory device.

Also, various embodiments of the present disclosure are directed to a memory device having a test scheme optimized according to a level of error correction capability of an error correction code (ECC) function in a memory system adopting an off-chip ECC function, and a testing method of the memory device.

In accordance with an embodiment of the present disclosure, a memory device may include: a memory circuit configured to generate a plurality of test data in a test mode; a plurality of comparator groups configured to generate first comparison signals based on part of the plurality of test data and part of a plurality of reference data during a first read operation period, and generate second comparison signals based on remaining test data and remaining reference data during a second read operation period; an error counter configured to generate first symbol information indicating a first number of errors occurring in the part of the plurality of test data, based on the first comparison signals during the first read operation period, and generate second symbol information indicating a second number of errors occurring in the remaining test data, based on the second comparison signals during the second read operation period; and an error determiner configured to generate a pass/fail signal indicating whether the memory circuit is normal, based on the first and second symbol information.

In accordance with an embodiment of the present disclosure, a memory device may include: a memory circuit configured to read N test data groups each having a first burst length in a test mode; and an error check circuit configured to divide the N test data groups into M target data groups each having a second burst length which is less than the first burst length, and generate a pass/fail signal indicating whether the memory circuit is normal, according to the number of errors occurring in the M target data groups in the test mode, where N is a natural number greater than 1.

In accordance with an embodiment of the present disclosure, a testing method of a memory device may include: setting expected data and reference number information; writing the expected data to a memory circuit; reading a plurality of test data from the memory circuit; checking a first number of errors occurring in part of the plurality of test data during a first read operation period; checking a second number of errors occurring in remaining test data during a second read operation period; summing the first number of errors and the second number of errors; and determining whether the memory circuit is normal, according to the reference number information and a total number of errors occurring in the plurality of test data.

### BRIEF DESCRIPTION OF THE DRAWINGS

FIG. 1 is a block diagram illustrating a configuration of a memory device in accordance with an embodiment of the present disclosure.

FIG. 2 is a block diagram illustrating a detailed configuration of an error check circuit illustrated in FIG. 1, in accordance with an embodiment of the present disclosure.

FIG. 3 is a block diagram illustrating a detailed configuration of a first comparator group illustrated in FIG. 2, in accordance with an embodiment of the present disclosure.

FIG. 4 is a block diagram illustrating a detailed configuration of an error counter illustrated in FIG. 2, in accordance with an embodiment of the present disclosure.

FIG. 5 is a block diagram illustrating a detailed configuration of an error determiner illustrated in FIG. 2, in accordance with an embodiment of the present disclosure.

FIG. 6 is a block diagram illustrating a detailed configuration of a summing circuit illustrated in FIG. 5, in accordance with an embodiment of the present disclosure.

FIG. 7 is a flowchart for describing a testing method of a memory device in accordance with an embodiment of the present disclosure.

FIG. 8 is a diagram for further describing the testing method of the memory device illustrated in FIG. 7, in accordance with an embodiment of the present disclosure.

### DETAILED DESCRIPTION

Various embodiments of the present disclosure are described below with reference to the accompanying drawings, in order to describe in detail the embodiments of the present disclosure so that those with ordinary skill in art to which the present disclosure pertains may easily carry out the technical spirit of the present disclosure.

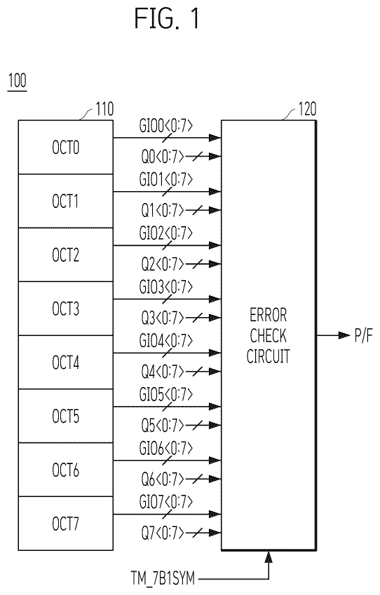

FIG. 1 is a block diagram illustrating a configuration of a memory device 100 in accordance with an embodiment of the present disclosure.

Referring to FIG. 1, the memory device 100 may include a memory circuit 110 and an error check circuit 120.

The memory circuit 110 may include N, where N is a natural number greater than 1, memory groups OCT0 to OCT7. In the present embodiment, it is described as an example that the memory circuit 110 includes first to eighth memory groups OCT0 to OCT7, that is, N=8. Each of the first to eighth memory groups OCT0 to OCT7 may be a memory area, and for example, the memory area may be a bank or a MAT (i.e., cell matrix).

The first to eighth memory groups OCT0 to OCT7 may read first to eighth test data groups as first to eighth read data groups GIO0<0:7> to GIO7<0:7>, respectively, in a test mode. Each of the first to eighth test data groups may include a plurality of test data generated from the respective first to eighth memory groups OCT0 to OCT7. Each of the first to eighth test data groups may have a first burst length. For example, the first burst length may be K, where K is a natural number greater than 1, corresponding to the number of data bits that are continuously read through the same read path, for example, a bit line and/or a global input/output line. In the present embodiment, it is described as an example that the first burst length corresponds to first to eighth data bits, that is, K=8.

The first to eighth memory groups OCT0 to OCT7 may read first to eighth normal data groups as the first to eighth read data groups GIO0<0:7> to GIO7<0:7>, respectively, in a normal mode.

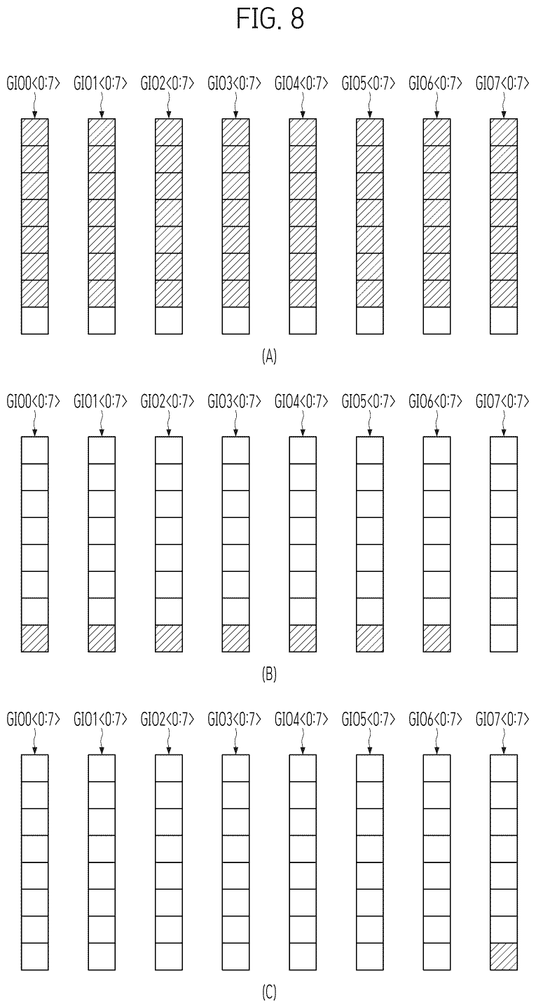

In the test mode, the error check circuit 120 may divide the first to eighth test data groups into M, where M is a natural number greater than N, target data groups based on the first to eighth read data groups GIO0<0:7> to GIO7<0:7>, and generate a pass/fail signal P/F indicating whether the memory circuit 110 is normal, according to the number of errors occurring in the M target data groups. In the present embodiment, it is described as an example that first to ninth target data groups are included, that is, M=9. Each of the first to ninth target data groups may have a second burst length. For example, the second burst length may be P, where P is a natural number less than K, data bits. Since the first to eighth test data groups are divided into the first to ninth target data groups, the second burst length may be less than the first burst length. In the present embodiment, it is described as an example that the second burst length corresponds to first to seventh data bits, that is, P=7. The first to ninth target data groups are described in more detail below (refer to FIG. 8).

For example, in the test mode, the error check circuit 120 may generate the pass/fail signal P/F based on the first to eighth read data groups GIO0<0:7> to GIO7<0:7> and first to eighth reference data groups Q0<0:7> to Q7<0:7>. More specifically, while the first to eighth reference data groups Q0<0:7> to Q7<0:7> are divided into first to ninth comparison data groups corresponding to the first to ninth target data groups, the error check circuit 120 may check the number of errors occurring in the first to ninth target data groups in units of groups based on the first to ninth target data groups and the first to ninth comparison data groups, and generate the pass/fail signal P/F based on first symbol information indicating a first number of errors occurring in the first to eighth target data groups among the first to ninth target data groups and second symbol information indicating a second number of errors occurring in the ninth target data group among the first to ninth target data groups.

In the normal mode, the error check circuit 120 may generate the pass/fail signal P/F indicating whether the memory circuit 110 is normal, according to the number of errors occurring in the first to eighth normal data groups based on the first to eighth read data groups GIO0<0:7> to GIO7<0:7>. For example, in the normal mode, the error check circuit 120 may check the number of errors occurring in the first to eighth normal data groups by comparing the first to eighth normal data groups with the first to eighth reference data groups Q0<0:7> to Q7<0:7>, respectively, and generate the pass/fail signal P/F corresponding to whether the memory circuit 120 is normal, according to the number of errors occurring in the first to eighth normal data groups.

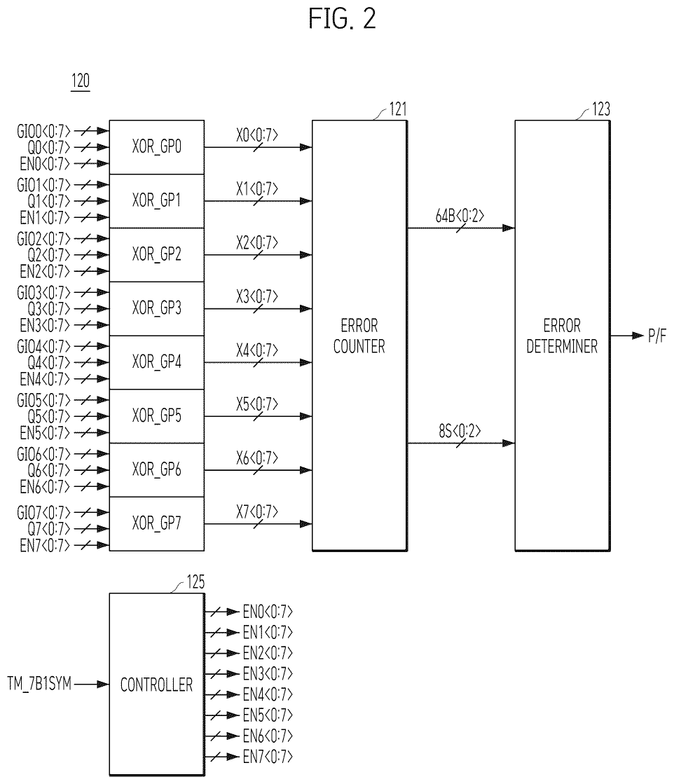

FIG. 2 is a block diagram illustrating a detailed configuration of the error check circuit 120 illustrated in FIG. 1, in accordance with an embodiment of the present disclosure.

Referring to FIG. 2, the error check circuit 120 may include first to eighth comparator groups XOR_GP0 to XOR_GP7, an error counter 121, an error determiner 123, and a controller 125.

The first to eighth comparator groups XOR_GP0 to XOR_GP7 may be configured to correspond to the first to eighth memory groups

OCT0 to OCT7, respectively. The first to eighth comparator groups XOR_GP0 to XOR_GP7 may generate first to eighth comparison signal groups X0<0:7> to X7<0:7> based on the first to eighth read data groups GIO0<0:7> to GIO7<0:7>, the first to eighth reference data groups Q0<0:7> to Q7<0:7> and first to eighth control signal groups EN0<0:7> to EN7<0:7>, respectively.

In the test mode, the first to eighth comparator groups XOR_GP0 to XOR_GP7 may generate the first to eighth comparison signal groups X0<0:7> to X7<0:7> corresponding to the first to eighth target data groups among the first to ninth target data groups during a first read operation period, and then generate the first to eighth comparison signal groups X0<0:7> to X7<0:7> corresponding to the ninth target data group among the first to ninth target data groups during a second read operation period. The second read operation period may be a period subsequent to the first read operation period. The first and second read operation periods may be allocated consecutively when a single read command is inputted. That is, the first and second read operation periods may be included in a single read operation period corresponding to the single read command.

In the normal mode, the first to eighth comparator groups XOR_GP0 to XOR_GP7 may collectively compare the first to eighth read data groups GIO0<0:7> to GIO7<0:7> with the first to eighth reference data groups Q0<0:7> to Q7<0:7> in units of bits, and generate the first to eighth comparison signal groups X0<0:7>to X7<0:7> corresponding to the first to eighth normal data groups.

In the test mode, the error counter 121 may generate the first symbol information indicating the first number of errors occurring in the first to eighth target data groups as first to third symbol signals 8S<0:2> based on the first to eighth comparison signal groups X0<0:7> to X7<0:7> during the first read operation period. In the test mode, the error counter 121 may generate the second symbol information indicating the second number of errors occurring in the ninth target data group as the first to third symbol signals 8S<0:2>based on the first to eighth comparison signal groups X0<0:7> to

X7<0:7> during the second read operation period.

In the normal mode, the error counter 121 may generate first to third count signals 64B<0:2> corresponding to the number of errors occurring in the first to eighth normal data groups, based on the first to eighth comparison signal groups X0<0:7> to X7<0:7>.

According to the present embodiment, the first to third count signals 64B<0:2> and the first to third symbol signals 8S<0:2> may be transmitted through different signal lines, for example, first to sixth signal lines or shared signal lines, for example, first to third signal lines.

In the test mode, the error determiner 123 may generate the pass/fail signal P/F according to the first and second numbers of errors based on the first to third symbol signals 8S<0:2>.

In the normal mode, the error determiner 123 may generate the pass/fail signal P/F according to the number of errors occurring in the first to eighth normal data groups, based on the first to third count signals 64B<0:2>.

The controller 125 may generate the first to eighth control signal groups EN0<0:7> to EN7<0:7> when a test mode signal TM_7B1SYM is activated (i.e., in the test mode). In the test mode, the first to eighth control signal groups EN0<0:7> to EN7<0:7> may be generated, i.e., activated and/or deactivated, in the same manner, and the first control signal group EN0<0:7> is representatively described below. In the test mode, first to seventh control signals EN0<0:6> corresponding to the first target data group among the control signals included in the first control signal group EN0<0:7> may be activated during the first read operation period, and eighth control signals EN0<7> corresponding to the ninth target data group among the control signals included in the first control signal group EN0<0:7> may be deactivated during the first read operation period. In the test mode, the first to seventh control signals EN0<0:6> corresponding to the first target data group among the control signals included in the first control signal group EN0<0:7>may be deactivated during the second read operation period, and the eighth control signal EN0<7> corresponding to the ninth target data group among the control signals included in the first control signal group EN0<0:7> may be activated during the second read operation period.

In the normal mode, the controller 125 may activate all control signals included in the first to eighth control signal groups EN0<0:7>to EN7<0:7>, when the test mode signal TM_7B1SYM is deactivated.

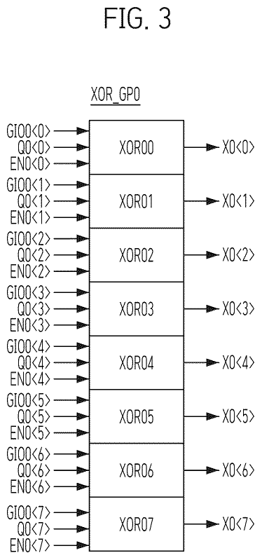

FIG. 3 is a block diagram illustrating a detailed configuration of the first comparator group XOR_GP0 illustrated in FIG. 2, in accordance with an embodiment of the present disclosure.

Referring to FIG. 3, the first comparator group XOR_GP0 may include first to eighth comparators XOR00 to XOR07. For example, each of the first to eighth comparators XOR00 to XOR07 may include an exclusive OR (XOR) gate.

The first to seventh comparators XOR00 to XOR06 may compare first to seventh target data GIO0<0:6> among first to eighth target data included in the first read data group GIO0<0:7> with first to seventh reference data Q0<0:6> among first to eighth reference data included in the first reference data group Q0<0:7>, and generate first to seventh comparison signals X0<0:6> corresponding to the comparison results, when the first to seventh control signals EN0<0:6>are activated during the first read operation period.

In the test mode, the first to seventh comparators XOR00 to XOR06 may generate the first to seventh comparison signals X0<0:6>corresponding to “pass” regardless of the first to seventh target data

GIO0<0:6> and the first to seventh reference data Q0<0:6>, when the first to seventh control signals EN0<0:6> are deactivated during the second read operation period.

In the test mode, the eighth comparator XOR07 may generate the eighth comparison signal X0<7> corresponding to “pass” regardless of the eighth target data GIO0<7> included in the first read data group GIO0<0:7> and the eighth reference data Q0<7> included in the first reference data group Q0<0:7>, when the eighth control signal EN0<7> is deactivated during the first read operation period. In the test mode, the eighth comparator XOR07 may compare

the eighth target data GIO0<7> included in the first read data group GIO0<0:7> with the eighth reference data Q0<7> included in the first reference data group Q0<0:7>, when the eighth control signal EN0<7> is activated during the second read operation period, and generate the eighth comparison signal X0<7> corresponding to the comparison result.

The first to eighth comparators XOR00 to XOR07 may compare first to eighth normal data included in the first read data group GIO0<0:7> with the first to eighth reference data included in the first reference data group Q0<0:7>, when the first to eighth control signals EN0<0:7> are activated in the normal mode, and generate the first to eighth comparison signals X0<0:7> corresponding to the comparison result.

Since each of the second to eighth comparator groups XOR_GP1 to XOR_GP7 may be designed in the same way as the first comparator group XOR_GP0, descriptions thereof are omitted.

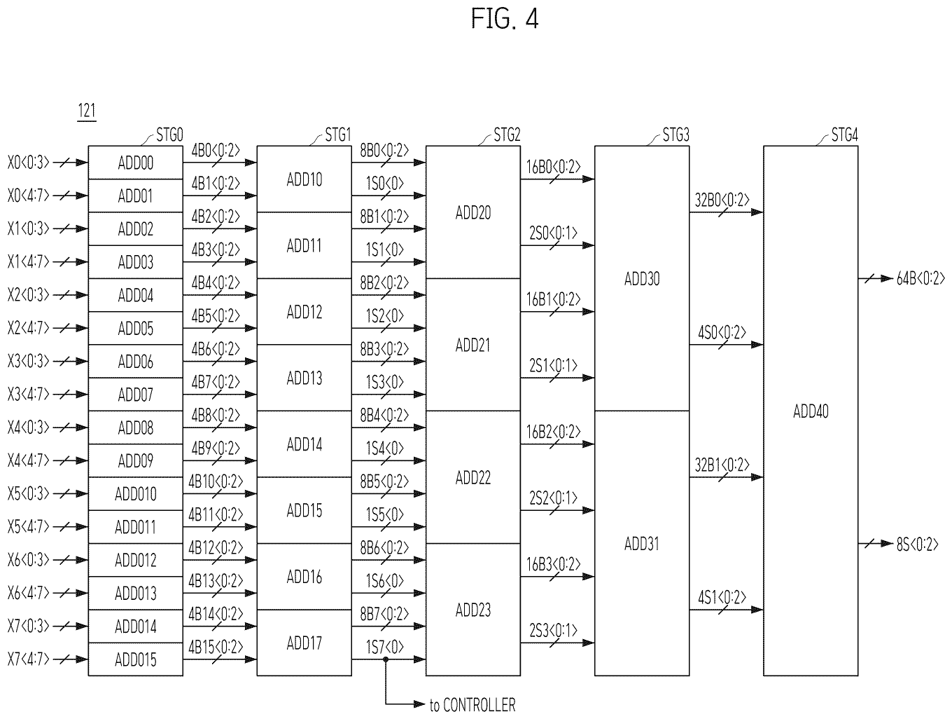

FIG. 4 is a block diagram illustrating a detailed configuration of the error counter 121 illustrated in FIG. 2, in accordance with an embodiment of the present disclosure.

Referring to FIG. 4, the error counter 121 may include first to fifth stages STG0 to STG4.

In the test mode, the first to fifth stages STG0 to STG4 may determine in units of groups whether an error has occurred in the first to seventh test data groups during the first read operation period, and sequentially accumulate the determination results. Accordingly, the first to fifth stages STG0 to STG4 may generate the first symbol information indicating the first number of errors as the first to third symbol signals 8S<0:2>.

In the test mode, the first to fifth stages STG0 to STG4 may determine in units of bits whether an error has occurred in the eighth test data group during the second read operation period, and sequentially accumulate the determination results. Accordingly, the first to fifth stages STG0 to STG4 may generate the second symbol information indicating the second number of errors as the first to third symbol signals 8S<0:2>.

In the normal mode, the first to fifth stages STG0 to STG4 may determine in units of bits the number of errors occurring in the first to eighth normal data groups, and sequentially accumulate the determination results. Accordingly, the first to fifth stages STG0 to STG4 may generate the first to third count signals 64B<0:2>corresponding to the number of errors.

The first stage STG0 may include first to 16^{th} adders ADD00 to ADD015. For example, each of the first to 16^{th} adders ADD00 to ADD015 may include a 2-bit adder.

In the test mode, the first and second adders ADD00 and ADD01 may generate first accumulated signal groups 4B0<0:2> and 4B1<0:2> corresponding to the number of errors occurring in the first target data group, based on the first comparison signal group X0<0:7>during the first read operation period. In the test mode, the first and second adders ADD00 and ADD01 may generate the first accumulated signal groups 4B0<0:2> and 4B1<0:2> corresponding to the number of errors occurring in first target data included in the ninth target data group, based on the first comparison signal group X0<0:7> during the second read operation period. In the normal mode, the first and second adders ADD00 and ADD01 may generate the first accumulated signal groups 4B0<0:2> and 4B1<0:2> corresponding to the number of errors occurring in the first normal data group, based on the first comparison signal group X0<0:7>.

Since each of the third to 16th adders ADD02 to ADD015 may be designed in the same way as the first adder ADD00 or the second adder ADD01, detailed descriptions thereof are omitted.

The second stage STG1 may include first to eighth adders ADD10 to ADD17. For example, each of the first to eighth adders ADD10 to ADD17 may include a 2-bit adder.

In the test mode, the first adder ADD10 may generate a first group accumulated signal 150<0> based on the first accumulated signal groups 4B0<0:2> and 4B1<0:2> during the first read operation period. For example, when the number of errors occurring in the first target data group is at least 1, the first adder ADD10 may activate the first group accumulated signal 150<0>. In the test mode, the first adder ADD10 may generate the first group accumulated signal 1S0<0>based on the first accumulated signal groups 4B0<0:2> and 4B1<0:2>during the second read operation period. For example, when an error occurs in the first target data included in the ninth target data group, the first adder ADD10 may activate the first group accumulated signal 1S0<0>. In the normal mode, the first adder ADD10 may generate first group count signals 8B0<0:2> based on the first accumulated signal groups 4B0<0:2> and 4B1<0:2>. For example, the first adder ADD10 may generate the first group count signals 8B0<0:2>corresponding to the number of errors occurring in the first normal data group.

According to an embodiment of the present disclosure, the first adder ADD10 may include a normal-only circuit for generating the first group count signals 8B0<0:2> and a test-only circuit for generating the first group accumulated signal 1S0<0>. According to another embodiment of the present disclosure, the normal-only circuit and the test-only circuit may be designed to have a structure in which a part of the normal-only circuit and a part of the test-only circuit are shared.

According to an embodiment of the present disclosure, the first group count signals 8B0<0:2> and the first group accumulated signal 150<0> may be transmitted through different signal lines, for example, first to fourth signal lines, or partially-shared signal lines, for example, first to third signal lines.

Since each of the second to eighth adders ADD11 to ADD17 may be designed in the same manner as the first adder ADD10, detailed descriptions thereof are omitted. However, in the test mode, the eighth adder ADD17 may generate an eighth group accumulated signal 1S7<0> based on eighth accumulated signal groups 4B14<0:2> and 4B15<0:2> during the second read operation period, and transmit the eighth group accumulated signal 1S7<0> to an external controller (not illustrated) (refer to (C) in FIG. 8). The controller may determine whether an error has occurred in the other target data (i.e., the remaining target data) based on the eighth group accumulated signal 1S7<0>.

The third stage STG2 may include first to fourth adders ADD20 to ADD23. For example, each of the first to fourth adders ADD20 to ADD23 may include a 2-bit adder.

In the test mode, the first adder ADD20 may generate accumulated information corresponding to a result of accumulating the number of errors occurring in the first target data group and the number of errors occurring in the second target data group as first and second group accumulated signals 250<0:1> based on the first group accumulated signal 150<0> and the second group accumulated signal 1S1<0> during the first read operation period. In the test mode, the first adder ADD20 may generate accumulated information corresponding to the number of errors occurring in the first target data and second target data included in the ninth target data group as the first group accumulated signals 250<0:1> based on the first group accumulated signal 150<0> and the second group accumulated signal 1S1<0> during the second read operation period. In the normal mode, the first adder ADD20 may generate accumulated information corresponding to a result of accumulating the number of errors occurring in the first normal data group and the number of errors occurring in the second normal data group as first group count signals 16B0<0:2> based on the first group count signals 8B0<0:2> and the second group count signals 8B1<0:2>.

According to an embodiment of the present disclosure, the second adder ADD20 may include a normal-only circuit for generating the first group count signals 16B0<0:2> and a test-only circuit for generating the first group accumulated signals 250<0:1>. According to another embodiment of the present disclosure, the normal-only circuit and the test-only circuit may be designed to have a structure in which a part of the normal-only circuit and a part of the test-only circuit are shared.

According to an embodiment of the present disclosure, the first group count signals 16B0<0:2> and the first group accumulated signals 250<0:1> may be transmitted through different signal lines, for example, first to fifth signal lines, or partially-shared signal lines, for example, first to third signal lines.

Since each of the second to third adders ADD21 to ADD23 may be designed in the same manner as the first adder ADD20, detailed descriptions thereof are omitted.

The fourth stage STG3 may include first and second adders ADD30 and ADD31. For example, each of the first and second adders ADD30 and ADD31 may include a 2-bit adder.

In the test mode, the first adder ADD30 may generate accumulated information corresponding to a result of accumulating the number of errors occurring in the first target data group, the number of errors occurring in the second target data group, the number of errors occurring in the third target data group and the number of errors occurring in the fourth target data group as first group accumulated signals 4S0<0:2> based on the first group accumulated signals 250<0:1> and the second group accumulated signals 2S1<0:1> during the first read operation period. In the test mode, the first adder ADD30 may generate accumulated information corresponding to a result of accumulating the numbers of errors occurring the first target data, the second target data, the third target data and the fourth target data included in the ninth target data group as the first group accumulated signals 4S0<0:2> based on the first group accumulated signals 250<0:1> and the second group accumulated signals 2S1<0:1> during the second read operation period. In the normal mode, the first adder ADD30 may generate accumulated information corresponding to a result of accumulating the number of errors occurring in the first normal data group, the number of errors occurring in the second normal data group, the number of errors occurring in the third normal data group and the number of errors occurring in the fourth normal data group as first group count signals 32B0<0:2> based on the first group count signals 16B0<0:2> and the second group count signals 16B1<0:2>.

According to an embodiment of the present disclosure, the first adder ADD30 may include a normal-only circuit for generating the first group count signals 32B0<0:2> and a test-only circuit for generating the first group accumulated signals 4S0<0:2>. According to another embodiment of the present disclosure, the normal-only circuit and the test-only circuit may be designed to have a structure in which a part of the normal-only circuit and a part of the test-only circuit are shared.

According to an embodiment of the present disclosure, the first group count signals 32B0<0:2> and the first group accumulated signals 4S0<0:2> may be transmitted through different signal lines, for example, first to sixth signal lines, or partially-shared signal lines, for example, first to third signal lines.

Since the second adder ADD31 may be designed in the same manner as the first adder ADD30, a detailed description thereof is omitted.

The fifth stage STG4 may include a first adder ADD40. For example, the first adder ADD40 may include a 2-bit adder.

In the test mode, the first adder ADD40 may generate accumulated information corresponding to a result (that is, the first number of errors) of accumulating the number of errors occurring in the first target data group, the number of errors occurring in the second target data group, the number of errors occurring in the third target data group, the number of errors occurring in the fourth target data group, the number of errors occurring in the fifth target data group, the number of errors occurring in the sixth target data group, the number of errors occurring in the seventh target data group and the number of errors occurring in the eighth target data group as the first to third symbol signals 8S<0:2> based on the first group accumulated signals 4S0<0:2> and the second group accumulated signals 4S1<0:2> during the first read operation period. In the test mode, the first adder ADD40 may generate accumulated information corresponding to a result of accumulating the numbers of errors occurring the first target data, the second target data, the third target data, the fourth target data, the fifth target data, the sixth target data, the seventh target data and the eighth target data included in the ninth target data group as the first to third symbol signals 8S<0:2> based on the first group accumulated signals 4S0<0:2> and the second group accumulated signals 4S1<0:2> during the second read operation period. In the normal mode, the first adder ADD40 may generate accumulated information corresponding to a result of accumulating the number of errors occurring in the first normal data group, the number of errors occurring in the second normal data group, the number of errors occurring in the third normal data group, the number of errors occurring in the fourth normal data group, the number of errors occurring in the fifth normal data group, the number of errors occurring in the sixth normal data group, the number of errors occurring in the seventh normal data group and the number of errors occurring in the eighth normal data group as the first to third group count signals 64B<0:2> based on the first group count signals 32B0<0:2> and the second group count signals 32B1<0:2>.

According to an embodiment of the present disclosure, the first adder ADD40 may include a normal-only circuit for generating the first group count signals 64B<0:2> and a test-only circuit for generating the first to third symbol signals 8S<0:2>. According to another embodiment of the present disclosure, the normal-only circuit and the test-only circuit may be designed to have a structure in which a part of the normal-only circuit and a part of the test-only circuit are shared.

According to an embodiment of the present disclosure, the first group count signals 64B<0:2> and the first to third symbol signals 8S<0:2> may be transmitted through different signal lines, for example, first to sixth signal lines, or partially-shared signal lines, for example, first to third signal lines.

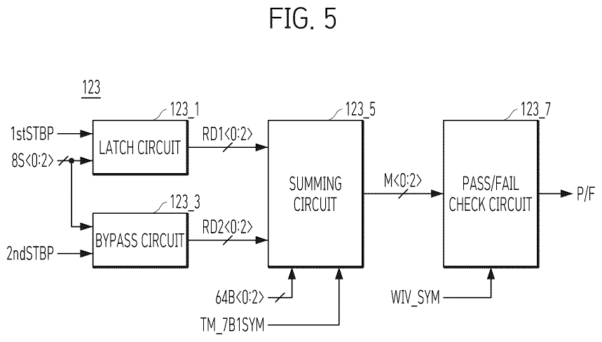

FIG. 5 is a block diagram illustrating a detailed configuration of the error determiner 123 illustrated in FIG. 2, in accordance with an embodiment of the present disclosure.

Referring to FIG. 5, the error determiner 123 may include a latch circuit 123_1, a bypass circuit 123_3, a summing circuit 123_5, and a pass/fail check circuit 123_7.

The latch circuit 123_1 may latch the first to third symbol signals 8S<0:2> corresponding to the first symbol information as first data RD1<0:2> according to a first strobe signal 1stSTBP that toggles at least during the first read operation period.

The bypass circuit 123_3 may bypass the first to third symbol signals 8S<0:2> corresponding to the second symbol information as second data RD2<0:2> according to a second strobe signal 2ndSTBP that toggles at least during the second read operation period.

The summing circuit 123_5 may sum the first data RD1<0:2>and the second data RD2<0:2>, and generate result data M<0:2>.

The pass/fail check circuit 123_7 may generate the pass/fail signal P/F based on the result data M<0:2> and reference number information WIV_SYM. For example, when a total number of errors, that is, the sum of the first number of errors and the second number of errors, which corresponds to the result data M<0:2>, is less than a reference number corresponding to the reference number information WIV_SYM, the pass/fail check circuit 123_7 may generate the pass/fail signal P/F corresponding to “pass”. On the other hand, when the total number of errors, that is, the sum of the first number of errors and the second number of errors, which corresponds to the result data M<0:2>, is greater than the reference number corresponding to the reference number information WIV_SYM, the pass/fail check circuit 123_7 may generate the pass/fail signal P/F corresponding to “fail”. The reference number may be set according to a level of error correction capability of an error correction code function of the controller.

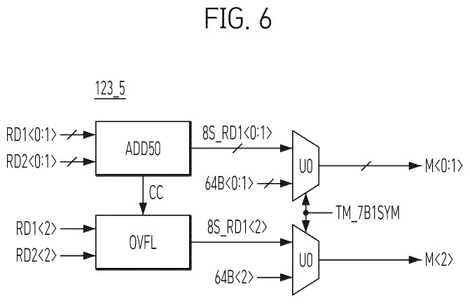

FIG. 6 is a block diagram illustrating a detailed configuration of the summing circuit 123_5 illustrated in FIG. 5, in accordance with an embodiment of the present disclosure.

Referring to FIG. 6, the summing circuit 123_5 may include an adder ADD50, an overflow detector OVFL, a first selector U0, and a second selector U1.

Referring to FIG. 6, the adder ADD50 may add part RD1<0:1>of the first data RD1<0:2> and part RD2<0:1> of the second data RD2<0:2>, and generate part 8S_RD1<0:1> of third data 8S_RD1<0:2> and an overflow signal CC.

The overflow detector OVFL may generate the other data (i.e., the remaining data) 8S_RD1<2> of the third data 8S_RD1<0:2> based on the other data RD1<2> of the first data RD1<0:2>, the remaining data RD2<2> of the second data RD2<0:2> and the overflow signal CC. For example, when the overflow signal CC is activated, the remaining data 8S_RD1<2> of the third data 8S_RD1<0:2> may be activated unconditionally. The overflow signal CC may be activated when the number of errors corresponding to part 8S_RD1<0:1> of the third data 8S_RD1<0:2> is greater than the reference number.

The first selector U0 may generate part 8S_RD1<0:1> of the third data 8S_RD1<0:2> or the first and second normal count signals 64B<0:1> as part M<0:1> of the result data M<0:2> according to the test mode signal TM_7B1SYM. For example, in the test mode, the first selector U0 may output part 8S_RD1<0:1> of the third data 8S_RD1<0:2> as part M<0:1> of the result data M<0:2>. In the normal mode, the first selector U0 may output the first and second normal count signals 64B<0:1> as part M<0:1> of the result data M<0:2>.

The second selector U1 may generate the remaining data 8S_RD1<2> of the third data 8S_RD1<0:2> or the third normal count signal 64B<2> as the remaining data M<2> of the result data M<0:2>according to the test mode signal TM_7B1SYM. For example, in the test mode, the second selector U1 may output the remaining data 8S_RD1<2> of the third data 8S_RD1<0:2> as the remaining data M<2> of the result data M<0:2>. In the normal mode, the second selector U1 may output the third normal count signal 64B<2> as the remaining data M<2> of the result data M<0:2>.

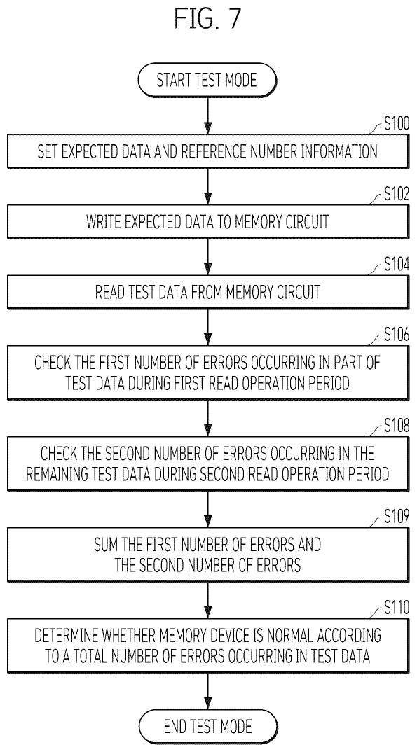

Hereinafter, an operation of the memory device 100 in accordance with an embodiment of the present disclosure, which has the above-described configuration, is described with reference to FIGS. 7 and 8.

FIG. 7 is a flowchart for describing a testing method of the memory device 100 in accordance with an embodiment of the present disclosure.

Referring to FIG. 7, the memory device 100 may set expected data and the reference number information WIV_SYM in operation S100. The expected data may be data corresponding to a low logic level, i.e., 0 or data corresponding to a high logic level, i.e., 1.

The memory device 100 may write the same data, that is, the expected data, to all first to eighth memory groups OCT0 to OCT7 included in the memory circuit 110, in operation S102.

The memory device 100 may read a plurality of test data corresponding to the expected data from the memory circuit 110, in operation S104.

The memory device 100 may check a first number of errors occurring in part of the plurality of test data during the first read operation period, in operation S106. For example, the memory device 100 may generate the first symbol information indicating the first number of errors occurring in the first to eighth target data groups among the first to ninth target data groups while the first to eighth memory groups OCT0 to OCT7 are divided into the first to ninth target data groups.

The memory device 100 may check a second number of errors occurring in the remaining data among the plurality of test data during the second read operation period, in operation S108. The memory device 100 may generate the second symbol information indicating the second number of errors occurring in the ninth target data group among the first to ninth target data groups while the first to eighth memory groups OCT0 to OCT7 are divided into the first to ninth target data groups.

The memory device 100 may sum the first number of errors and the second number of errors, in operation S109, and determine whether the memory circuit 110 is normal according to the reference number information WIV_SYM and the total number of errors occurring in the plurality of test data, that is, the first number of errors+the second number of errors, in operation S110.

When the overflow signal CC is activated in at least one of the operation S106 of checking the first number of errors, the operation S108 of checking the second number of errors and the operation of summing the first number of errors and the second number of errors, the operation S110 of determining whether the memory circuit 110 is normal may determine that the memory circuit 110 is defective regardless of the total number of errors occurring in the test data.

FIG. 8 is a diagram for further describing the testing method of the memory device 100 illustrated in FIG. 7, in accordance with an embodiment of the present disclosure.

Referring to FIG. 8, part of the plurality of test data may include part (shaded portions in (A) of FIG. 8) of data bits that are continuously read through the same read path. Part of the data bits (shaded portions in (A) of FIG. 8) may correspond to the first to eighth target data groups. The first number of errors occurring in the first to eighth target data groups may be checked during the first read operation period.

Other bits (shaded portions in (B) of FIG. 8) of the plurality of test data may correspond to the ninth target data group. The second number of errors occurring in the ninth target data group may be checked during the second read operation period.

The remaining bits (shaded portion in (C) of FIG. 8) of the plurality of test data may be provided to the controller during the second read operation period.

According to an embodiment of the present disclosure, there is an advantage of being able to check whether a memory circuit is normal or not through an optimized test scheme based on the number of errors occurring in a plurality of target data groups divided according to a level of error correction capability.

According to an embodiment of the present disclosure, it is possible to contribute to improve the yield of a memory device by having an optimized test scheme according to a level of error correction capability.

According to an embodiment of the present disclosure, it is possible to contribute to improve the yield of a memory device since a memory system adopting an off-chip error correction code (ECC) function has an optimized test scheme according to a level of error correction capability of the ECC function.

While the present disclosure has been illustrated and described with respect to specific embodiments, the disclosed embodiments are provided for the description, and not intended to be restrictive. Further, it is noted that the an embodiments of present disclosure may be achieved in various ways through substitution, change, and modification that fall within the scope of the following claims, as those skilled in the art will recognize in light of the present disclosure. Furthermore, the embodiments may be combined to form additional embodiments.

What is claimed is:

1. A memory device comprising:
a memory circuit configured to generate a plurality of test data in a test mode;
a plurality of comparator groups configured to generate first comparison signals based on part of the plurality of test data and part of a plurality of reference data during a first read operation period, and generate second comparison signals based on remaining test data and remaining reference data during a second read operation period;
an error counter configured to generate first symbol information indicating a first number of errors occurring in the part of the plurality of test data, based on the first comparison signals during the first read operation period, and generate second symbol information indicating a second number of errors occurring in the remaining test data, based on the second comparison signals during the second read operation period; and
an error determiner configured to generate a pass/fail signal indicating whether the memory circuit is normal, based on the first and second symbol information.

2. The memory device of claim 1, wherein each of the plurality of comparator groups includes:
P comparators configured to compare P bits among K bits included in a first burst length of corresponding test data among the plurality of test data with P bits among K bits included in the burst length of corresponding reference data among the plurality of reference data, and generate corresponding first comparison signals among the first comparison signals corresponding to the comparison result, where P is a natural number less than K, and K is a natural number greater than 3; and
(K-P) comparators configured to compare (K-P) bits among the K bits included in the first burst length of the corresponding test data among the plurality of test data with (K-P) bits among the K bits included in the first burst length of the corresponding reference data among the plurality of reference data, and generate at least one corresponding second comparison signal among the second comparison signals corresponding to the comparison result.

3. The memory device of claim 1,
wherein the error counter includes a plurality of stages,
wherein the plurality of stages generate the first symbol information indicating the first number of errors by determining, in units of groups, whether an error occurs in the part of the plurality of test data and sequentially accumulating the determination results during the first read operation period, and
wherein the plurality of stages generate the second symbol information indicating the second number of errors by determining, in units of bits, whether an error occurs in the remaining test data and sequentially accumulating the determination results during the second read operation period.

4. The memory device of claim 1, wherein the error determiner includes:
a latch circuit configured to latch the first symbol information as first data based on a first strobe signal that toggles during at least the first read operation period;
a bypass circuit configured to bypass the second symbol information as second data based on a second strobe signal that toggles during at least the second read operation period;
a summing circuit configured to sum the first data and the second data and generate result data; and
a pass/fail check circuit configured to generate the pass/fail signal based on the result data.

5. The memory device of claim 4, wherein the summing circuit includes:
an adder configured to add part of the first data and part of the second data and generate part of third data and an overflow signal;
an overflow detector configured to generate remaining third data based on remaining first data, remaining second data and the overflow signal;
a first selector configured to generate part of the third data or part of normal information, which indicate the number of errors occurring in the memory circuit in a normal mode, as part of the result data based on a test mode signal corresponding to the test mode; and
a second selector configured to generate the remaining third data or remaining normal information as remaining result data based on the test mode signal.

6. The memory device of claim 1,
wherein the memory circuit reads a plurality of normal data in a normal mode, and
wherein, in the normal mode, the error check circuit checks the number of errors occurring in the normal data in units of bits based on the plurality of normal data and a plurality of normal reference data and generates the pass/fail signal corresponding to whether the memory circuit is normal, according to the number of errors occurring in the normal data.

7. A memory device comprising:
a memory circuit configured to read N test data groups each having a first burst length in a test mode; and
an error check circuit configured to divide the N test data groups into M target data groups each having a second burst length which is less than the first burst length, and generate a pass/fail signal indicating whether the memory circuit is normal, according to the number of errors occurring in the M target data groups in the test mode, where N is a natural number greater than 1.

8. The memory device of claim 7, wherein the error check circuit checks the number of errors occurring in the M target data groups based on the M target data groups and M reference data groups, and generates the pass/fail signal based on first symbol information indicating a first number of errors occurring in first groups among the M target data groups and second symbol information indicating a second number of errors occurring in at least one second group among the M target data groups.

9. The memory device of claim 7, wherein the error check circuit includes:
N comparator groups configured to generate first comparison signal groups corresponding to first groups among the M target data groups during a first read operation period, and generate a second comparison signal group corresponding to at least one second group among the M target data groups during a second read operation period, based on the N test data groups and N reference data groups;
an error counter configured to generate first symbol information indicating a first number of errors occurring in the first groups, based on the first comparison signal groups during the first read operation period, and generate second symbol information indicating a second number of errors occurring in the second group, based on the second comparison signal group during the second read operation period; and
an error determiner configured to generate the pass/fail signal based on the first and second symbol information.

10. The memory device of claim 9, wherein each of the N comparator groups includes:
P comparators configured to compare P bits among K bits included in the first burst length of a corresponding test data group among the N test data groups with P bits among K bits included in the burst length of a corresponding reference data group among the N reference data groups, and generate corresponding first comparison signals among the first comparison signal groups corresponding to the comparison result, where P is a natural number less than K, and K is a natural number greater than 3; and
(K-P) comparators configured to compare (K-P) bits among the K bits included in the first burst length of the corresponding test data group among the N test data groups with (K-P) bits among the K bits included in the first burst length of the corresponding reference data group among the N reference data groups, and generate at least one corresponding second comparison signal of the second comparison signal group corresponding to the comparison result.

11. The memory device of claim 9,
wherein the error counter includes a plurality of stages,
wherein the plurality of stages generate the first symbol information indicating the first number of errors by determining, in units of groups, whether an error occurs in the first groups and sequentially accumulating the determination results during the first read operation period, and
wherein the plurality of stages generate the second symbol information indicating the second number of errors by determining, in units of bits, whether an error occurs in the second group and sequentially accumulating the determination results during the second read operation period.

12. The memory device of claim 9, wherein the error determiner includes:
a latch circuit configured to latch the first symbol information as first data based on a first strobe signal that toggles during at least the first read operation period;
a bypass circuit configured to bypass the second symbol information as second data based on a second strobe signal that toggles during at least the second read operation period;
a summing circuit configured to sum the first data and the second data and generate result data; and
a pass/fail check circuit configured to generate the pass/fail signal based on the result data.

13. The memory device of claim 12, wherein the summing circuit includes:
an adder configured to add part of the first data and part of the second data and generate part of third data and an overflow signal;
an overflow detector configured to generate remaining third data based on remaining first data, remaining second data and the overflow signal;
a first selector configured to generate part of the third data or part of normal information, which indicate the number of errors occurring in the memory circuit in a normal mode, as part of the result data based on a test mode signal corresponding to the test mode; and
a second selector configured to generate the remaining third data or remaining normal information as remaining result data based on the test mode signal.

14. The memory device of claim 7,
wherein the memory circuit reads normal data in a normal mode, and
wherein, in the normal mode, the error check circuit checks the number of errors occurring in the normal data in units of bits based on the normal data and second reference data, and generates the pass/fail signal corresponding to whether the memory circuit is normal, according to the number of errors occurring in the normal data.

15. A testing method of a memory device, the testing method comprising:
setting expected data and reference number information;
writing the expected data to a memory circuit;
reading a plurality of test data from the memory circuit;
checking a first number of errors occurring in part of the plurality of test data during a first read operation period;
checking a second number of errors occurring in remaining test data during a second read operation period;
summing the first number of errors and the second number of errors; and
determining whether the memory circuit is normal, according to the reference number information and a total number of errors occurring in the plurality of test data.

16. The testing method of claim 15, wherein, when an overflow signal is activated in at least one of the checking the first number of errors, the checking the second number of errors and the summing the first number of errors and the second number of errors, the determining whether the memory circuit is normal determines that the memory circuit is defective regardless of the total number of errors occurring in the test data.

17. The testing method of claim 15, wherein the part of the plurality of test data includes part of data bits that are continuously read through a same read path, and the remaining test data include the other data bits.
